(19) United States
(12) Patent Application Publication
(10) Pub. No.: US 2007/0273394 A1
(43) Pub. Date: Nov. 29, 2007

(54) Environmental sensor

(75) Inventors: Philip Tanner, Nathan (AU); Peter Johnson, Nathan (AU); David Thiel, Nathan (AU); Takeharu Suzuki, Nathan (AU); Richard Adamec, Nathan (AU); Peter Henry William Beadle, Chipping Norton (AU)

Correspondence Address: CONNOLLY BOVE LODGE & HUTZ LLP, 1875 EYE STREET, N.W., SUITE 1100, WASHINGTON, DC, 20036, US

(73) Assignee: M.B.T.L. Limited, Hawthorn (AU)

(21) Appl. No.: 10/558,695

(22) PCT Filed: Jun. 7, 2004
(86) PCT No.: PCT/AU04/00744

§ 371 Date: Aug. 2, 2006

(30) Foreign Application Priority Data
Jun. 6, 2003 (AU) 2003902836

(51) Int. Cl. G01R 27/26

(52) U.S. Cl. 324/664; 73/866.1

(57) ABSTRACT

Multi functional sensors are described. A silicon based sensor utilizes metal layers arranged as resistors around a central pair if resistors separated by a humidity sensitive polymer with one of the central resistors being a heater. This enables temperature humidity wind speed and direction to be measured. In another embodiment an array of resistors is printed onto a flexible substrate to form the basis of an array of sensors. A soil moisture sensor, which is also useful as a leaf wetness sensor, incorporates a novel self calibrating capacitive sensor structure. The flexible substrate is rolled into a stake that can be inserted in the soil so that below ground sensors measure soil moisture and above ground sensors measure temperature, light, humidity, wind speed and direction.

This invention relates to sensors for measuring environmental parameters including temperature, humidity, air flow and soil moisture using micro electronic sensors.

### BACKGROUND TO THE INVENTION

U.S. Pat. Nos. 5,029,101 and 5,117,359 disclose non integrated sensor assemblies for measuring temperature humidity and wind speed.

Airflow sensors using heated resistors and temperature sensors to measure flow are known and typical forms of these are disclosed in U.S. Pat. Nos. 5,108,193 and 57,080,205.

U.S. Pat. No. 6,035,711 discloses a wind sensor utilizing two measuring circuits and four heating elements.

Humidity has been measured as disclosed in U.S. Pat. Nos. 4,965,698 and 505,434 by measuring variations in capacitance using a polyimide film.

Combination sensors have also been proposed. U.S. Pat. No. 5,918,110 discloses a combination pressure and electrochemical sensor. U.S. Pat. 5,929,344 discloses a multiple resistive temperature sensors which minimizes the number of conductors used.

Soil sensors have been proposed. U.S. Pat. No. 542,649 discloses a soil moisture sensor. U.S. Pat. No. 5,841,282 discloses a device mounted on a ground engaging implement such as a coulter to measure soil conductivity. U.S. Pat. No. 5,933,015 uses time domain reflectometry to measure soil density and moisture content.

Capacitive sensors which are usual in micro devices do have calibration problems. U.S. Pat. No. 6,201,399 seeks to overcome the problem by using a direct measurement sensor for calibration. In WO99/10714 a two sensor system is disclosed for measuring liquid levels which doesn't need recalibration for different liquids.

There is a need for inexpensive, unobtrusive sensors that can be used in a wireless form in applications such as agriculture, horticulture and buildings. The sensors discussed above are not suitable for such applications and are usually too expensive.

It is an object of this invention to provide sensors that can be used to sense a variety of parameters and which are inexpensive to produce deploy and maintain.

### BRIEF DESCRIPTION OF THE INVENTION

To this end the present invention provides an environmental sensor which includes
a) a silicon substrate
b) a first metal layer on said silicon substrate
c) a water vapour sensitive polymer layer on said first metal layer
d) a second metal layer on said water vapour sensitive polymer to define a capacitive humidity sensor
e) an insulating layer over said second metal layer
f) at least four symmetrically placed resistors on said insulating layer to define an airflow sensor.

Preferably an insulating layer such as silicon nitride is coated on the surface of the silicon substrate and the first metal layer is deposited onto the insulating layer. Preferably the second metal layer also functions as a heater. The combined sensor is able to measure temperature, wind direction, wind speed and humidity. The resistors can act as temperature sensors and heating elements. The ambient temperature is measured by measuring the resistance of any or all of the resistors when the current flowing through the heaters is low enough to prevent self heating. With a higher value of current through the heaters, the heater temperature increases significantly above ambient and changes in resistance of the heaters provides a measure of the air flow across the heater array giving data that provides a measure of wind speed and direction. The capacitance between the two central metal layers varies with changes in humidity affecting the water vapor sensitive polymer preferably a polyimide dielectric layer. The electronics controlling the operation of the sensors and collecting the data is preferably placed on the reverse face of the silicon wafer and enclosed in an insulator such as polyimide or polycarbonate. Alternatively, the control and interface electronics can be placed alongside the sensors but protected by a capping layer such as silicon nitride and/or polyimide. Other sensors may be mounted on the silicon substrate including a light sensor or gas sensors. A light sensor may be incorporated with the CMOS circuitry in the form of a photodiode as long as the capping layer is transparent to visible light.

The electronics module preferably includes a transmitter that enables data from the sensor to be transmitted to a central control module. This means the sensor may be repositioned without any need for rewiring. The sensor may include battery power or may utilize an ambient energy harvester to recharge the battery or provide the necessary power. The energy harvester may be a photo electric cell, a motion sensitive generator using magneto or piezo devices to generate a current or an induction device mounted adjacent power cables to parasitically generate current.

This micro sensor is useful in buildings as a relocatable environmental sensor to sense temperature light and humidity. It is also useful in horticulture and agriculture to collect data on environmental conditions in a crop. Preferably the sensor is combined with a soil moisture sensor and a leaf wetness sensor. The soil moisture or leaf wetness sensor may be a capacitive sensor.

In another aspect of this invention there is provided a capacitive sensor which may be used for measuring soil moisture or leaf wetness, which includes at least one pair of sensor pads one of each pair consisting of a conductor covered by a dielectric layer and the other of each pair consisting of a conductor covered by the same dielectric layer with a top conducting layer. This arrangement has the advantage of providing the second sensor pad as a reference capacitor so that manual calibration of the sensor is unnecessary.

In a further aspect this invention provides a soil moisture sensor consisting of
a) a body portion for insertion into the soil
b) a surface on said body portion adapted to contact with the soil
c) a plurality of sensor locations on said surface interconnected by conductive layers
d) each sensor includes a conductive layer on said surface and a dielectric layer on said conductive layer
e) a pair of sensors are used to determine the upper and lower capacitance values
f) an electronic support circuit which sends an interrogation pulse to each sensor and records the return signal.

Preferably the sensor includes at least a primary and a secondary electrode, and at lest one shared reference electrode. Both primary and secondary sensor electrodes consists of a conductive area covered by a dielectric layer with the secondary electrode being then covered completely by a top conducting layer which is connected to the shared reference electrode, or may be a continuation of it. The secondary sensor electrode acts as a reference capacitor to allow automatic calibration of the primary sensor electrode against manufacturing variables such as variations in dielectric thickness and electronic component variability.

Ideally the sensor is formed on a flexible polymer substrate by printing the conductive electrodes onto the substrate followed by printing a dielectric layer over both the conductive electrodes. A further conductive layer is then printed over both sides of the entire sensor except for the area immediately over the primary electrode which is to be used to make the measurement. This conductive area must also completely cover all sensor interconnections (wiring). A further improvement can be made by the additional of a dummy sensor's wiring. The wiring should be similar in surface area to that of the other two sensor's wiring but the electrode itself is not present. This trinary sensor then provides information about the parasitic capacitance of the interconnection and electronic components which can then be used to further improve the quality of the measurement. The secondary and trinary sensors can now be used to set upper and lower values for the range of the primary sensor. The two calibration sensors can be used to calibrate a multiple of primary sensors.

Other sensors relying on capacitance changes can be made by rearranging the electrode structure. By way of example, a leaf wetness sensor can be formed by using an interdigit electrode structure.

A combined soil and environment sensor may be formed on a flexible film. In a further aspect of this invention there is provided a sensor array for horticultural and agricultural use which includes
a) a flexible substrate
b) at least one sensor selected from temperature, humidity, light, wind and leaf wetness sensors printed or mounted on said flexible substrate
c) capacitive moisture sensors printed on said flexible substrate at a location remote from said at least one sensor
d) support electronics for the sensors a) and b) mounted and/or printed on said flexible substrate
e) an antenna printed on said flexible substrate.

The flexible substrate may be mountable on a support structure or alternatively is able to be folded or rolled into a self supporting stake that can be inserted in the ground so that the soil moisture capacitive sensors are in contact with the soil and the other sensors are elevated above the ground. The various other sensors may be integrated or separately printed on to the substrate. The wind sensors may be a set of strain gauges located to sense the force and direction of moving air on the vertically oriented substrate. The leaf wetness sensor may be oriented to receive condensation while the humidity sensor is preferably sheltered from direct exposure.

In combination the environmental sensor will provide the farmer or horticulturalist with regular transmitted readings of all the relevant parameters that can influence crop productivity including soil moisture, temperature, wind conditions, humidity, light conditions and leaf wetness.

These sensors may also be used in forestry or fire prone areas as fire hazard sensors.

The combined environmental sensors of this invention may also be adapted for use in buildings where they can be easily relocated.

Because the flexible substrate supported sensors are fabricatable by screen printing techniques they lend themselves to inexpensive mass manufacture with the consequent advantage of being relatively low cost. This means that the sensors can be disposable.

In one preferred embodiment the substrate is biodegradable so that when used in agriculture they can be ploughed into the ground at the end of the growing season. Suitable materials include biodegradable polyesters or blends of biodegradable synthetic polymers with starch. Suitable polyesters include Mater-Bi by Novamont, Ecoflex by BASF and Bionelle from Showa Denko.

Where multiple sensors are used the central controller is programmed to use an addressing protocol to sequentially collect readings from each individual sensor on each combined sensor unit.

### DETAILED DESCRIPTION OF THE INVENTION

Some preferred embodiments of the invention will now be described with reference to the drawings in which:

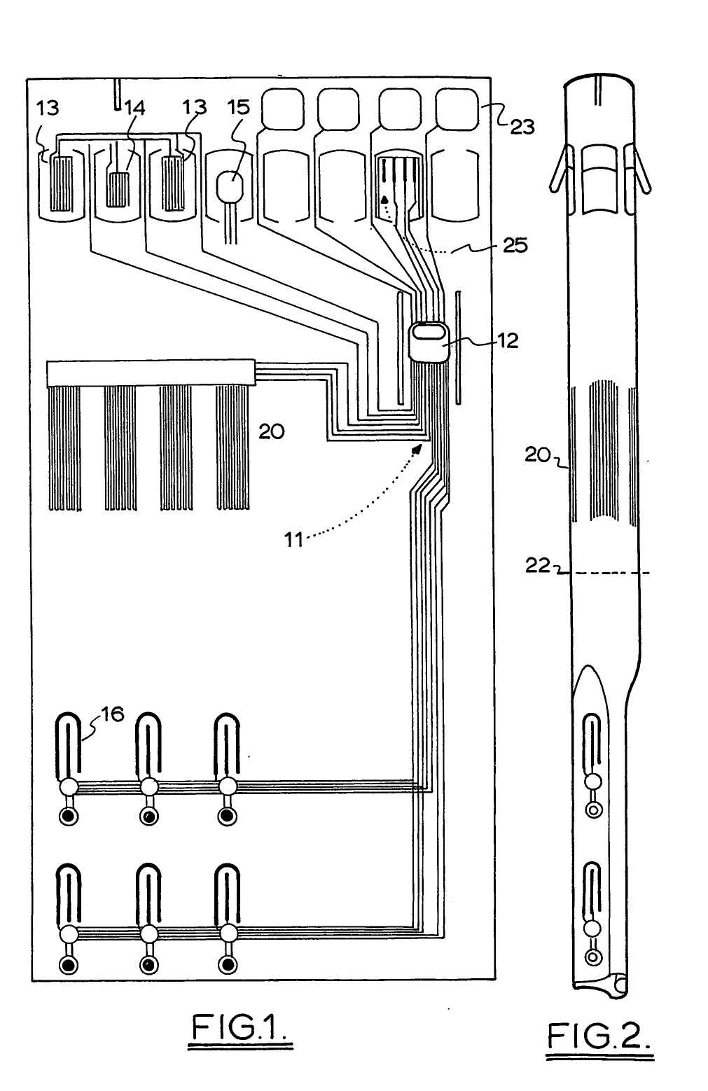

FIG. 1 is a schematic outline of a multi sensor layout on a flexible substrate;

FIG. 2 illustrates the multi sensor of figure in rolled into the form of a stake;

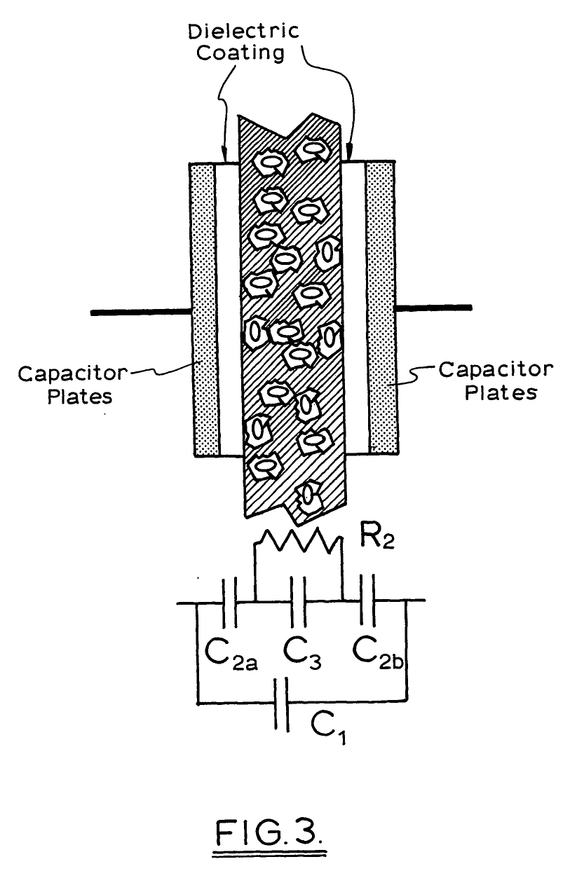

FIG. 3 illustrates the operation of the capacitive moisture sensor used in the multi sensor of FIG. 1;

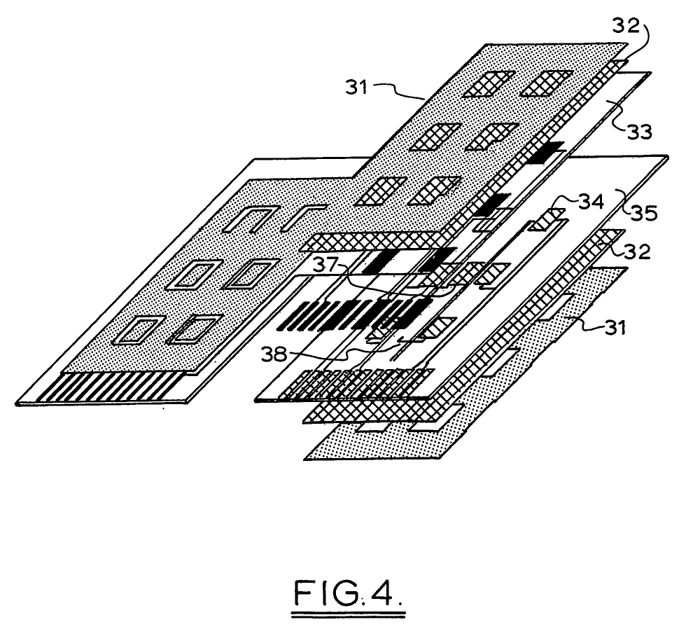

FIG. 4 illustrates the layers forming a printed soil sensor;

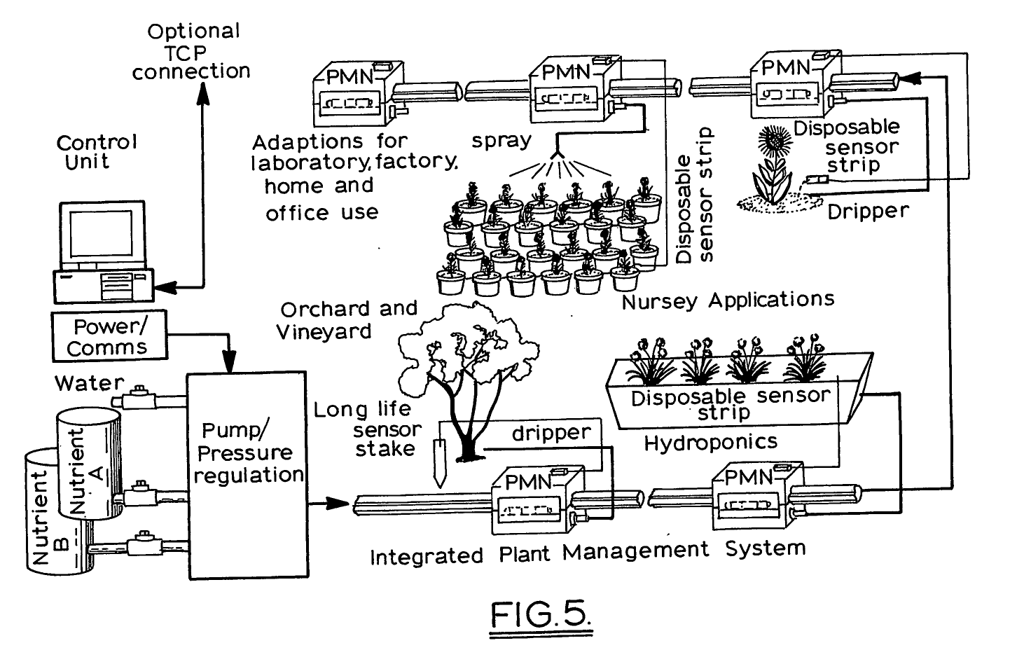

FIG. 5 illustrates a plant management system utilizing the sensor array of FIGS. 1 and 2;

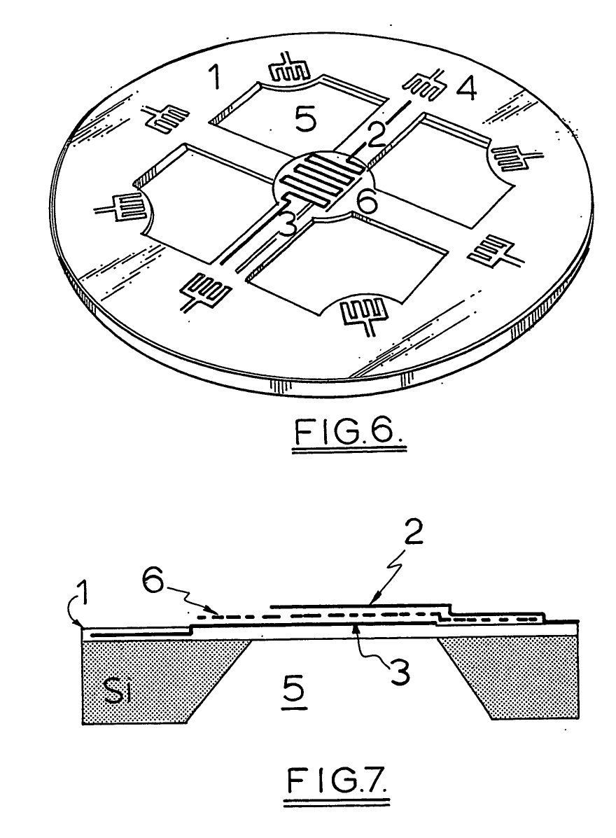

FIG. 6 is a schematic view of a combined silicon based temperature wind and humidity sensor;

FIG. 7 is a side view of FIG. 5;

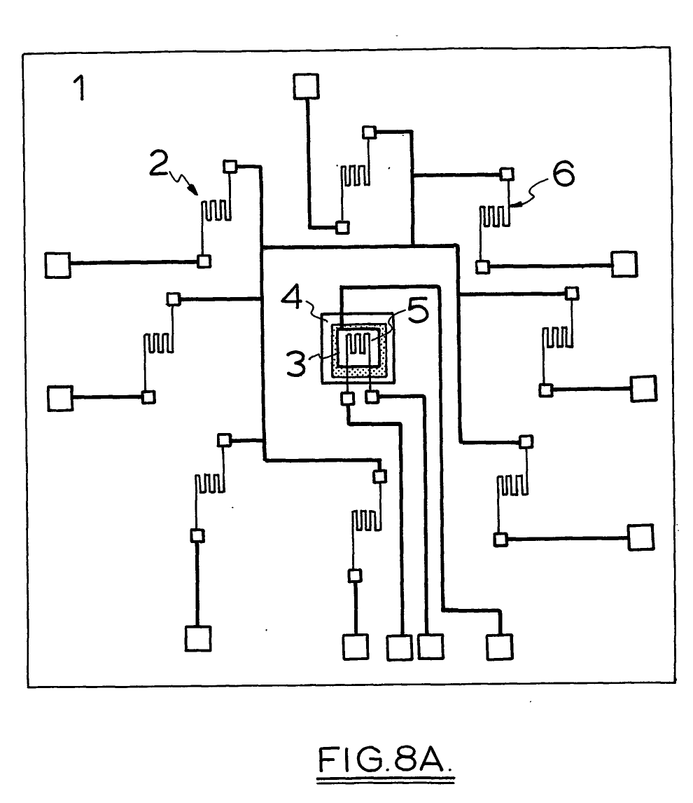

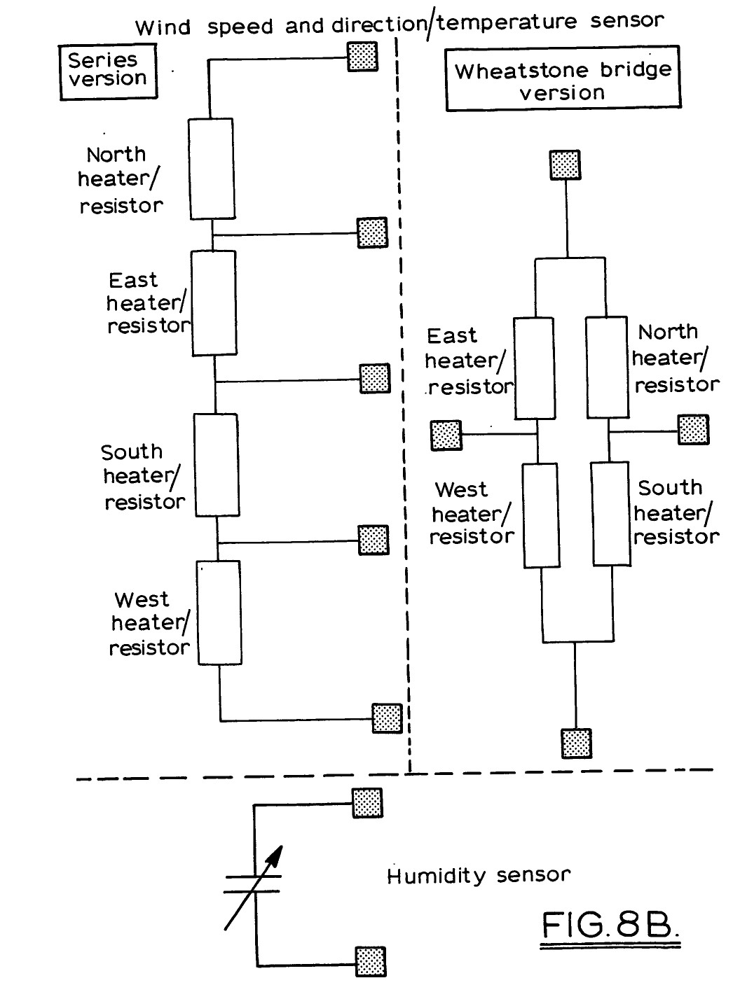

FIG. 8A is a schematic circuit diagram of the sensor of FIG. 5;

FIG. 8B is a schematic layout of alternative electrical circuits for the wind speed/direction and temperature sensor of FIG. 5;

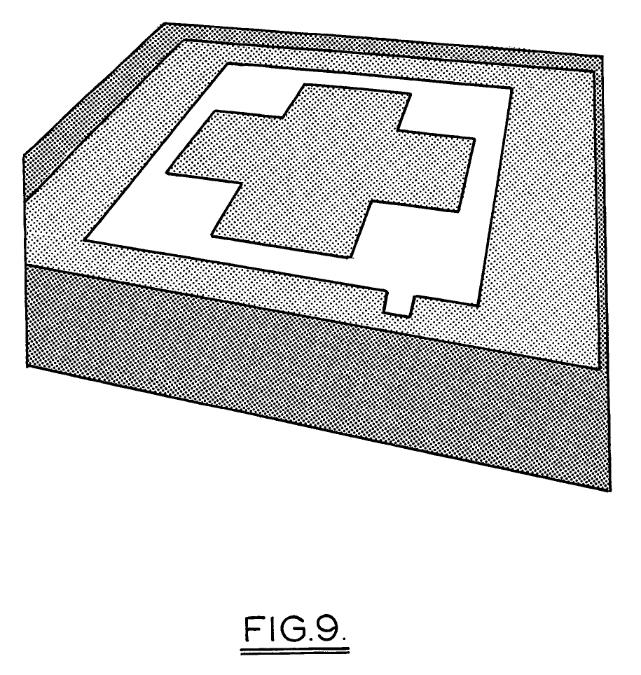

FIGS. 9 to 15 illustrate the masks used to fabricate the sensor illustrated in FIG. 6.

As shown in FIGS. 1 and 2 conductive layers are printed onto a flexible polymer substrate and other components are adhered to it. The sensor is controlled by the integrated electronics microcontroller 11 with a transmitter and circuitry for the various sensors. The below surface sensors 16 include capacitive sensors for assessing soil moisture and sensors for salinity and nutrient content. The above ground sensors include light sensor 12, leaf wetness sensors 13, humidity sensor 14 and an alternative micro electronic wind sensor 15. Strain gauges 20 arranged to lie in the 4 cardinal directions are used to detect wind speed and direction. Antennas 23 are arranged at the top of the substrate and the battery and power unit is held inside the rolled up substrate and connected to the controller via the power connector 25.

Arrays of sensors and support electronics are assembled on a flexible substrate. The circuitry formed on the substrate as well as providing interconnection, also forms some of the sensor electronics and sensing surfaces. Active materials forming part of the sensors are attached to the substrate by gluing, printing, or otherwise depositing. The flexible circuit can be manufactured, tested and supplied flat and rolled or otherwise formed into the active shape at time of use. The act of forming, rolling etc can be used to activate the sensors. Many components can be formed on the substrate surface including capacitors, resistors, inductors, transformers, transistors, batteries, antennas. In the case of a sensor array inserted in the soil, a special insertion tool can form and insert the sensor array in the soil.

In FIG. 3 the additional electrodes used for calibration are not shown. With reference to FIG. 3 the soil moisture sensor capacitance functions as follows:
C3 charges in series with C2 with its charge dissipated in R2
R2 dependant on the conductivity of the soil but becomes irrelevant with soils of normal conductivity
C3 is effectively shorted out by R2 in soil of normal conductivity
C1 is the fixed capacitance of the sensor wiring
C2 varies with soil moisture content

Different charge/discharge curves are observed for different soil moisture content Insulated electrode sensors relying on capacitive effects for the measurement of water in soils require some method to compensate for manufacturing and other variables. Some such variables are the variation in insulation thickness overlaying the electrodes and the variation in hysteresis levels in Schmitt trigger input circuitry. Variations also occur due to temperature. In a soil sensor small local variations(such as voids) in the soil around the sensor can lead to erroneous results. In the cases of the soil moisture sensor and leaf wetness version of the same sensor, variations in the applied dielectric coating may also effect the sensor sensitivity and reading to moisture. By placing two sensors in close proximity to each other one sensor has a conductive layer placed over its probes on top of the common dielectric coating of both sensors. Since the dielectric is common to both, any variations in the dielectric will affect both sensors similarly. This sensor acts as a calibration reference for the other sensor.

In a disposable sensor as proposed in this invention the manufacturing costs need to be minimised, ruling out the individual calibration of each sensor.

This invention overcomes these problems by the combined use of multiple sensors and reference sensors to set the range of capacitance values covered by the sensor.

This sensor can be manufactured using screen-printing or other techniques geared towards the automated printing or placing of conductive and insulating coatings on to different substrates. As shown in FIG. 4 screen-printing of conductive layers 31 and 32 (silver 32 and graphite loaded 31) paints and UV cured insulation layers 33 onto polyester film 35 is used to construct a sensor. Areas of conductive paint/ink form one of the sensors capacitor electrodes. Each is insulated from the soil by the polyester substrate 35 on one side and by a UV cured dielectric 33 screen-printed over the sensor electrode and interconnections. A conductive layer of graphite loaded paint 31 is applied over a silver mesh 32 to form a large grounded conductive layer and applied to the front and back of the sensor) except over the primary sensor electrodes 34. This layer may be left uninsulated from the soil so that the soil forms the other plate of the capacitor or it may be insulated from the soil.

The upper 37 and lower 38 bounds sensor electrodes/interconnects are printed over with conductive ink and form a reference capacitor whose value is dependant on the insulator thickness and allows a measure of the maximum and minimum possible capacitance.

All sensor electrode interconnection traces are shielded by the top and bottom ground layers and care is taken to ensure each sensor electrode interconnection trace is similar in area to every other. This allows the use of an extra trace of similar dimensions to be printed along with the other traces. This can be used to measure the stray wiring capacitance and hence the minimum possible capacitance. Hence the minimum and maximum values can be used to adjust and scale the actual sensor readings. This technique avoids the need for factory calibration of each sensor.

By using additional sensors for one measurement, the readings from each sensor electrode can be compared and only those with sensible and comparable readings used to form the final output.

Alternatively additional sensor electrodes or groups of sensor electrodes can be arranged to generate a profile of the soil moisture or other variable. In the case of a soil moisture sensor, by measuring the soil moisture using six separate sensors the effect of voids and other discontinuities in the soil can be compensated for. Using this scheme it is easy to set up an array of calibrated sensors.

A further variation may be to make either the calibration sensor probes or the charging resistor much larger than the actual sensor probes, but with all other circuitry. By activating both sensors at the same time, the calibration sensor capacitor will stay within the more linear region of its charge curve. When the sensor capacitor reaches some preset value the value on the calibration capacitor is sampled and held for output as the read value. This is another way to remove any manufacturing or other variables effecting both sensors.

The sensor used for sensing soil moisture is easily adapted for use as a leaf wetness sensor such as 13 in FIG. 1.

CMOS(Complementary Metal Oxide Semiconductor) logic is well known for its low power requirements, especially when the logic state is not changing There are advantages in designing a sensor to use CMOS logic. By sending a interrogation (or strobe) pulse to such a sensor the sensor only draws current for the duration of the measurement and then returns to the quiescent state. Further minimisation is possible by removing the power from the sensor whilst not in use, but has the disadvantage of increased complexity and the need to delay the reading until the sensor has stabilised.

Two or more sensors can share a common output line to save wiring. Each sensor when interrogated will pull the common output line into the opposite state to its normal quiescent state in order to assert its own output conditions on the common output line. (similar to the Wired OR in computer logic). Suitable methods to ensure only one sensor is active at any one time are necessary.

Methods to activate sensors:
Several input lines can be used together where the combined states of the lines uniquely identify a particular sensor. A sensor becomes active when it recognizes its code on the lines.
A common serial input line can be used to activate a particular sensor by carrying a unique serial code for each sensor. A sensor only activates if it recognizes its code.
A pulse on a single input line applied to the input of a counter. Each applied input pulse increments the counter which then activates each sensor in turn.
A single pulse on the input line to the first sensor causes it to activate, on completion it generates a new pulse which is applied to the next sensor which in turn activates the next, and so on.

FIG. 5 illustrates a plant management system. The system monitors and controls the water and nutrient levels in the soil feeding individual or groups of plants. Integrated sensors for nutrient, temperature and moisture are placed in the soil adjacent to the plant. The integrated sensor which may be disposable or non-disposable connects to a drip/spray feed micrometering valve unit incorporating its own remotely programmable microcontroller. This plant management node can monitor the soil conditions and adjust water and nutrient levels according to the program stored. Communications, power, water and several nutrients are delivered via a specially molded cable/pipe and the individual management nodes simply clamp on to the cable/pipe making all connections at once. Each plant management node can be interrogated and programmed from a central control unit which might itself be remotely controlled.

The system is based around a Plant Management Node(PMN) which through its own built in electronics and micro-metering valves can apply nutrients and water to individual plants or small groups of plants. It monitors the levels of these using a sensor array placed in the soil adjacent to the plant/plants being managed. The nutrient and watering requirements are stored on board in its own memory which can be written and read by a Control unit which oversees a number of PMNs. The power and communications are delivered over a single pair of wires moulded into the pipe delivering water and nutrients to each PMN. The pipe also consists of several channels for water and separate nutrients as well as the two wires just mentioned.

Each PMN is constructed as a Clam Shell such that closing the unit onto the cable causes the water and nutrient channels to be pierced by suitable connectors so as the water and nutrient become available to the PMN. Similarly the Power/Communications pair is also connected to with a suitable connector.

The PMN incorporates several micro-metering valves or pumps each connected to its own inlet and connecting to a common outlet. This allows the controlled delivery of water and nutrients to the outlet. The outlet can then be applied to its plant through a variety of methods including but not limited to, spray, drip feed and underground soaker.

Each PMN is separately identified by an address either allocated to it at manufacture or at installation. This might be done by having each PMN ‘learn’ its address when first clamped on to the live pipe/cable or first powered up when manufactured. The address can be stored in non-volatile memory. Alternatively the address could be mask programmed in at manufacture. This address should be displayed on each PMN as a bar code or some other machine readable code as well as having a numeric identifier for humans.

Timing synchronisation can be done over the power/communications cable.

The soil sensors could came in several forms each housing specific sensors for various chemicals and water. These forms might be:
a long life stake for orchard and vineyard as well as some nursery applications,
a disposable laminated plastic slip which is clipped onto a non-disposable peg which houses some interface electronics and a means to connect to the sensor slip.
For hydroponics the sensor might be inside a tube through which the nutrient solution circulates.
For applications within factories and laboratories the sensors might carry different chemical or biological sensors suitable to the process being controlled.
The PMN might have provision for the soil sensor stake to be clipped on to it so as to increase the ease of use in orchard and vineyard applications and to provide a support for the PMN. The PMN is clipped on to the Sensor Stake, clamped on to the Pipe/cable and pushed into the ground. A drip tube is connected to the outlet and positioned away from the sensor but near the plant.

In FIGS. 6-8 an integrated silicon based sensor is illustrated. The multi sensor combines humidity, temperature, wind speed, (or air flow rate) and wind direction on a single substrate. The sensors measure environmental parameters by observing changes in resistance or capacitance and are directly interfaced with a microprocessor to facilitate periodic measurement using low levels of power. Humidity Temperature and wind velocity sensor

As shown in FIG. 6 a silicon wafer is initially coated back and front with a dielectric layer 1 of low stress silicon oxy nitride or silicon nitride of about 1-1.5 micron thickness. Windows are opened in the dielectric on the back surface of the wafer. A thin metal film is deposited and patterned to act as one electrode of the capacitive humidity sensor. A humidity sensitive layer 6, preferably polyimide, is then deposited and photodefined. A second thin metal film is then deposited and patterned to form the second electrode of the humidity sensor.

A second insulating polymer film, preferable polyimide, is then deposited and photodefined to provide insulation between the humidity sensor electrodes and the wind and temperature sensing elements. A third metal film is then deposited and patterned to act as both the heaters and temperature sensing resistors for the wind and ambient temperature sensors.

Silicon, not covered by silicon oxy nitride or silicon nitride, is anisotopically etched to form a pit that undercuts the sensor layers to leave them suspended on a thermally isolated dielectric membrane. The dielectric layer on the back prevents any etching of that surface.

The device includes a central heater 2 a second electrode 3, a set of eight peripheral electrodes 4 and windows 5.

The electrode structure can take any of the usual forms. The electrodes employed may be interdigitated, parallel-plate with interdigitated top and bottom electrodes, parallel-plate with array of square holes in top electrode, parallel-plate with slotted top electrode, porous parallel-plate with/without perforated top electrode, and polarity-reversed interdigitated. A parallel plate with an array of square holes in the top electrode gives a near linear response to humidity measurement with polyimide.

Temperature is sensed by measuring the resistance of any or all of the heater electrodes to give a measure of ambient temperature. This can be done, for example, by connecting the sensor to a constant current source of approximately 0.5 mA and measuring the voltage across the resistor. Metals such as nickel and platinum are suitable.

Humidity is sensed by measuring the change in capacitance between the two electrodes as the dielectric constant of the polyimide changes with humidity. The sensor may be connected as part of an oscillator circuit thus producing a square wave signal whose frequency varies with the capacitance value of the sensor.

Wind speed is sensed in either of two ways:
(a) by maintaining the total resistance of all heaters and consequently their average temperature at a constant value, preferably 100-150° C. The power needed to maintain the value is indicative of wind speed.
(b) by applying a constant current to the heaters. The voltage drop across the heaters is indicative of wind speed.

Wind direction is based on the hot wire anemometer principle. When current is passed through the heaters and their temperature is raised above ambient, preferably 100-150° C., they will reach different temperatures depending on the wind direction. The relative temperature and hence resistance of the geometrically opposed heaters, north-south and east-west, will be indicative of the wind direction.

In FIG. 8A a slightly different arrangement is illustrated. Nine windows are opened in the dielectric layer on the back of the silicon wafer and the silicon anisotopically etched through to the top layer dielectric layer 1 to form thermally isolated diaphragms 2. On the central diaphragm a metal plate electrode 3 is deposited followed by a layer of polyimide 4 and then by metal track 5 which acts a both the top electrode of the capacitive humidity sensor and the central heater. Metal tracks 6 are also deposited on to the eight peripheral diaphragms to act as temperature and wind direction sensors.

FIG. 8B illustrates the wind direction sensor and the four cardinal point resistors arranged as a series connection or as a wheatstone bridge.

The steps to fabricate the sensor of FIGS. 6-8 are:

Step 1 Mask 1

Silicon nitride on silicon substrate
Deposit silicon nitride layers (≈1.5 um thick) on both front and back sides of entire silicon substrate.
Open windows in silicon nitride on the back to expose silicon, which will be etched away at the end to form nitride diaphragm at front.

Step 2 Mask 2 see FIG. 9

Bottom electrode of humidity sensor-nickel Deposit nickel by sputtering (≈0.15 um thick).
Pattern photolithographically

Spin photoresist, define the pattern with mask shown photolithographically, and develop photoresist. Etch the nickel not covered by photoresist. Strip photoresist.

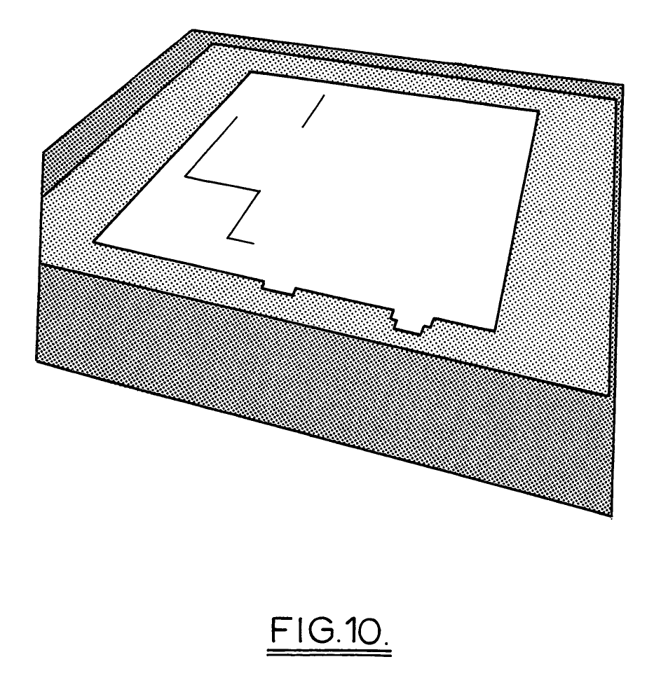

Step 3 Mask 3 see FIG. 10

Humidity sensing dielectric layer-polyimide Spin polyimide (≈0.4 um thick), define the pattern with mask shown photolithographically, and develop polyimide. Cure polyimide thermally(350° C.).

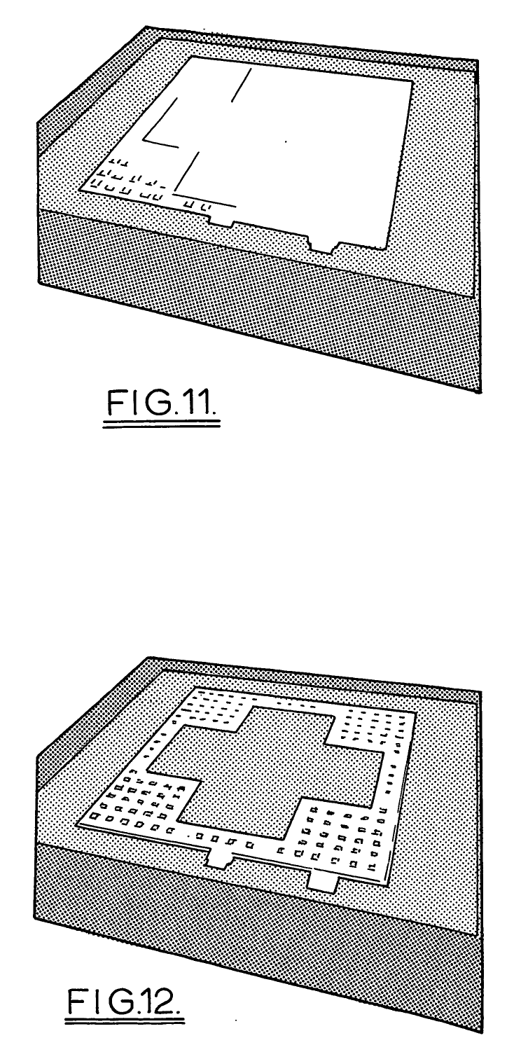

Step 4 Mask 4 see FIG. 11

2^{nd} dielectric layer with holes to diffuse moisture-polyimide Spin polyimide (≈0.4 um thick), define the pattern with mask shown photolithographically, and develop polyimide.

Cure polyimide thermally(350° C.).

Step 5 Mask 5 see FIG. 12

Top electrode of humidity sensor-nickel
Deposit nickel by sputtering (≈0.15 um thick).
Pattern photolithographically

Spin photoresist, define the pattern with mask shown photolithographically, and develop photoresist. Etch the nickel not covered by photoresist. Strip photoresist

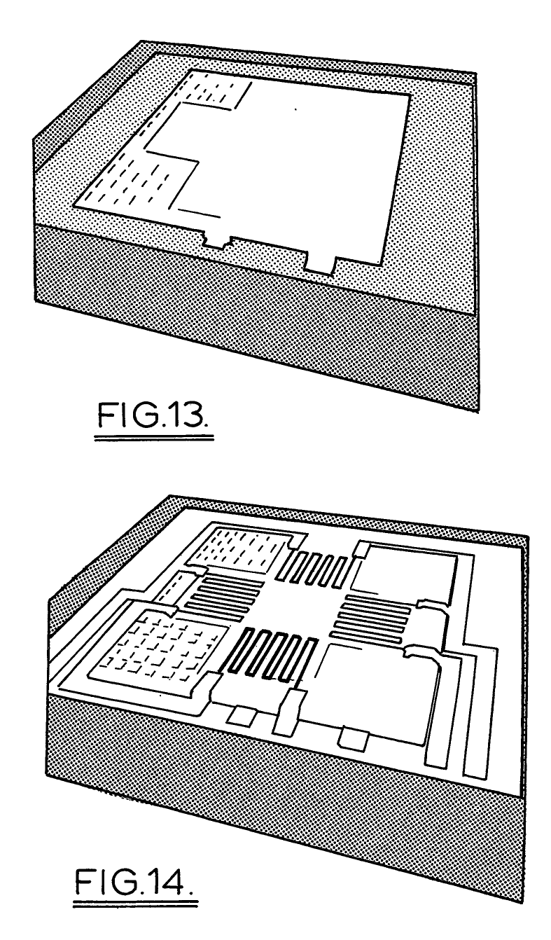

Step 6 Mask 3 see FIG. 13

Insulating layer-polyimide Spin polyimide (≈0.4 um thick), define the pattern with mask shown photolithographically, and develop polyimide.
Cure polyimide thermally (350° C.).

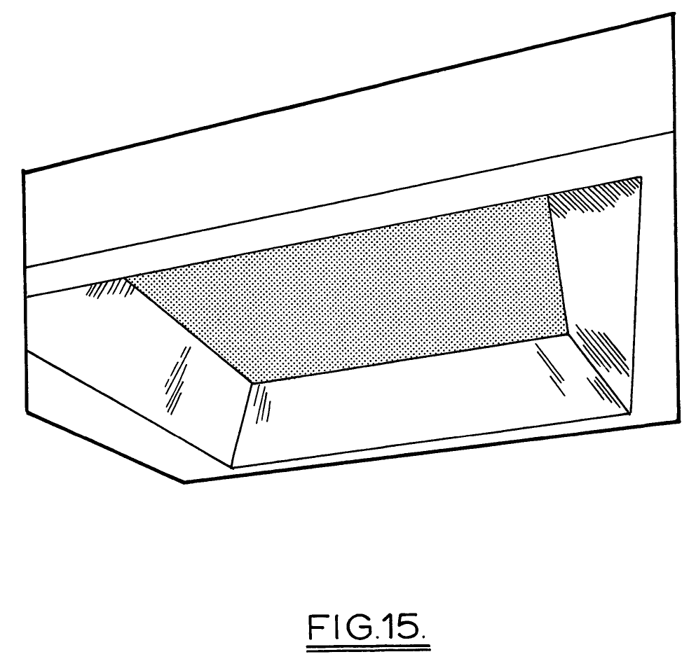

Step 7 Mask 6 see FIG. 14

Heaters for wind speed/direction and temperature sensor-nickel
Deposit nickel by thermal evaporation (≈0.4 um thick).
Pattern photolithographically

Spin photoresist, define the pattern with mask shown photolithographically, and develop photoresist. Etch the nickel not covered by photoresist. Strip photoresist.

Step 8 MASK 1 see FIG. 15

Backside-etched hole with underside of silicon nitride membrane visible (backside view)
Etch silicon in TMAH or KOH which is defined by window opening at the beginning

NB: Front side structure is sealed from etchant by o-ring or resin coating.

From the above those skilled in the art will see that the present invention provides a general environmental sensor that can be made using mass production techniques to provide a relatively low cost sensor. Those skilled in the art will realize that other embodiments and process routes may be envisaged without departing from the core teachings of this invention.

1. A sensor array for horticultural and agricultural use which includes
a) a substrate
b) at least one sensor selected from temperature, humidity, light, wind and leaf wetness sensors printed or mounted on said substrate
c) capacitive moisture sensors printed on said substrate at a location remote from said at least one sensor
d) support electronics for the sensors a) and b) mounted and/or printed on said substrate
e) an antenna printed on said substrate.

2. A capacitive sensor which may be used for measuring soil moisture or leaf wetness, which includes at least one pair of sensor pads one of each pair consisting of a conductor covered by a dielectric layer and the other of each pair consisting of a conductor covered by the same dielectric layer with a top conducting layer.

3. A soil moisture sensor consisting of
a) a body portion for insertion into the soil
b) a surface on said body portion adapted to contact with the soil
c) a plurality of sensor locations on said surface interconnected by conductive layers
d) each sensor includes a conductive layer on said surface and a dielectric layer on said conductive layer
e) a pair of sensors are used to determine the upper and lower capacitance values
f) an electronic support circuit which sends an interrogation pulse to each sensor and records the return signal.

4. An environmental sensor which includes
a) a substrate comprising silicon coated front and back with a dielectric layer
b) a first metal layer on said substrate
c) a water vapour sensitive polymer layer on said first metal layer
d) a second metal layer on said water vapour sensitive polymer to define a capacitive humidity sensor
e) an insulating layer over said second metal layer
f) a plurality of symmetrically placed resistors on said insulating layer to define an airflow sensor in combination with a heating element.

5. An environmental sensor as claimed in claim 4 which also includes an etch pit in the silicon beneath the sensor layers that forms a thermally isolated membrane.

6. An environmental sensor as claimed in claim 4 in which the dielectric layer is silicon nitride or silicon oxynitride.
